(19) United States
(12) Patent Application Publication
(10) Pub. No.: US 2010/0328189 A1
(43) Pub. Date: Dec. 30, 2010

(54) Process for Electrically Interconnecting Two Components

(75) Inventors: Mourad Laknin, Vitre (FR); Laurent Garnier, Moulins (FR)

Correspondence Address: COHEN, PONTANI, LIEBERMAN & PAVANE LLP, 551 FIFTH AVENUE, SUITE 1210, NEW YORK, NY, 10176, US

(73) Assignee: Oberthur Technologies, Levallois Perret (FR)

(21) Appl. No.: 12/826,378

(22) Filed: Jun. 29, 2010

(30) Foreign Application Priority Data
Jun. 29, 2009 (FR) 0954412

(51) Int. Cl. H01Q 1/00; H05K 7/02; H05K 3/30

(52) U.S. Cl. 343/904; 361/767; 29/832

(57) ABSTRACT

One component is provided with an electrical connection wire and the other component is provided with an electrical connection pad. The process includes a wire routing step along at least one out-and-back path so as to form at least first and second rectilinear portions on the outward and return paths while running through at least one loop connecting the two portions. In addition, the process includes a step for attaching the wire to the pad at at least one electrical conduction point in such a way that each of the rectilinear portions is connected to the pad.

### BACKGROUND OF THE INVENTION

1. Field of the Invention

The present invention is directed to a process for interconnecting a first component having an electrical connection wire and a second component having an electrical connection pad. The invention is also directed to an integrated circuit card socket including two components interconnected according to the interconnection process of the invention, and an integrated circuit card which includes such a socket. The invention applies more particularly but not specifically to the field of chip cards using a <<contactless>> interface.

2. Description of the Related Art

Chip cards include a near-field communication component, such as a magnetic antenna allowing so-called <<contactless>> communication to be established. This near-field communication antenna is made up of an electrically conducting wire coiled into a plurality of electrically conductive turns. Such an antenna is provided with two electrical connection wires, each consisting of the ends of the antenna wire.

Usually, the socket is made up of a body in which the antenna is incorporated. In addition, the socket incorporates a second component such as the contact lands for connecting the antenna to the integrated circuit. These lands are each provided with a connection pad for connecting to one of the antenna connection wires.

Such a socket is known in the state of the art, more particularly from document WO 2008/129526. In this document, each of the antenna's electrical connecting wires is connected to a metal land by laser bonding. Thus, each of the antenna's electrical connecting wires runs over the land, being connected to the land by at least one bond point.

The disadvantage of this connection is that the antenna and the land are subject to disconnection in the event of bending or twisting of the card body, which can lead to bad contacts and short-circuits between the integrated circuit components and the antenna. As a result, a large number of integrated circuit cards are defective and must be ultimately rejected during their manufacture, which is relatively costly.

### SUMMARY OF THE INVENTION

More particularly, an embodiment of the invention has the purpose of proposing a process for interconnecting two components of which one includes an electrical connection wire and the other an electrical connection pad, in particular an antenna and a land, allowing the realization of a connection that is reliable and resistant to spurious distortions of the card.

To this end, an embodiment of the invention provides a process for connecting a first component provided with an electrical connection wire and a second component provided with an electrical connection pad, wherein the following steps are included:
laying out the wire along at least one out-and-back path so as to form at least first and second substantially rectilinear portions on the outward and return paths respectively, passing through at least one loop interconnecting the two portions,
attachment of the wire to the pad at at least one electrical conduction point, such that each of the rectilinear portions is electrically connected to the pad.

Thanks to this connection process, the characteristics of the connection between the two components are improved in terms of reliability and of resistance to bending.

The presence of the connecting wire loop allows, on the one hand, a double connection of the wire attaching to the pad, and on the other hand a relatively large pad attachment area delimited by the two portions and the wire loop.

The electrical conduction point makes it possible not only to provide the electrical conduction between the two components, but also the mechanical attachment of the wire to the pad.

Of course, the connecting wire can be routed along a more complex path including several out-and-back paths arranged in a zigzag and as many conduction points as portions, or possibly fewer conduction points than portions provided that each portion of the connecting wire is electrically connected to the pad of the second component.

In one particular embodiment of the invention, the rectilinear portions are connected to the pad at at least two electrical conduction points laid out so that each runs respectively over both rectilinear portions.

Even if, during twisting, one of the portions of the loop is separated from the connection pad, the other portion allows electrical interconnection of the two components to be provided.

In another particular embodiment of the invention, the rectilinear portions are connected to the pad at a conduction point laid out so as to run over the two rectilinear portions.

In this case, the rectilinear portions are very close to one another. It is thus possible to consider that the two rectilinear portions form a single portion with an equivalent diameter equal to twice the diameter of each portion. Hence the connection between the wire and the pad at the conduction point is more rigid. The mechanical strength of the socket under bending and torsion is thereby improved.

A process according to an embodiment of the invention may in addition include one or more of the features according to which:
the step of attaching the wire to the pad is carried out by thermocompression, for example through the use of ultrasonic means;
the wire is positioned with respect to the connection pad in such a way that the two rectilinear portions run facing the pad;
one of the rectilinear portions including the end of the wire, this portion is arranged so that the end extends beyond the pad.

Another embodiment of the invention is directed to an integrated circuit card socket, including a card body formed in a mass of material incorporating first and second components respectively provided with an electrical connection wire and an electrical connection pad, wherein the first and second components are connected in accordance with a process according to the invention.

A socket according to an embodiment of the invention may include one or another of the features according to which:
the body is formed by lamination of a stack of layers, one of the layers incorporating at least one of the two components;
the second component is either a contact land or a connection post for an electronic component such as an integrated circuit;
the loop extends beyond the pad, the loop is embedded in the mass of the material forming the body;
the second component includes another connection pad and the first component is provided with another connecting wire, the pads and the wires being interconnected according to a process according to the invention;
the second component includes at least a contact land provided with a first electrical connection pad for the wire from the first component and a second pad, opposite the first pad, for electrical connection to an integrated circuit held by the socket;
the first component includes an antenna which includes a plurality of turns coiled along the periphery of the socket.

Finally, another embodiment of the invention is directed to an integrated circuit card, including an integrated circuit and a card socket bearing an integrated circuit, provided with a cavity to receive the integrated circuit, wherein, the card socket being according to the invention, the first component includes an antenna and the second component includes a connection post of the integrated circuit or a contact land for connecting to the integrated circuit's antenna.

### BRIEF DESCRIPTION OF THE DRAWINGS

Other features and advantages will appear in the light of the following description, which refers to the appended drawings in which:

FIG. 1 is a transverse section of an integrated circuit card according to a first embodiment of the invention;

FIG. 2 is a bottom view of the card socket of FIG. 1, in which an antenna and metal contact lands are shown transparently;

FIG. 3 is a perspective view of the socket of FIG. 2 bearing the antenna and the lands;

FIG. 4 is a transverse section of the socket of FIG. 1 before lamination of the socket layers and machining of a cavity for receiving an integrated circuit module; and

FIG. 5 is a perspective view of the socket of a card according to a second embodiment of the invention.

### DETAILED DESCRIPTION OF THE PRESENTLY PREFERRED EMBODIMENTS

An integrated circuit card assigned the overall reference 10 is shown in FIG. 1.

Card 10 includes a socket 12 defining the body 14 of the card 10 formed within the mass of the material, made up in this example essentially of a plastic material.

In this example, card 10 includes an integrated circuit module 16. This module 16 includes a microcircuit 18 and a module socket 20 defining two opposite faces called internal 22A and external 22B, internal face 22A bearing the integrated circuit 18 (also designated electronic chip).

In addition, in this example, as illustrated in FIG. 1, the card socket 12 includes a cavity 24 for housing integrated circuit module 16.

More particularly, cavity 24 is made up of a deep central area 26 provided with a bottom 28, for housing the integrated circuit, and a peripheral area 30, elevated with respect to central area 26, defining a step 32 with bottom 28. This peripheral area 30 includes a bearing surface raised with respect to bottom 28 of cavity 24 in which rest the edges of module socket 20.

Such a cavity 24 is generally obtained by machining, typically by milling, or by spot facing in two operations:
one wide spot facing to form peripheral area 30 corresponding to the depth of step 32,
one small spot facing to form deeper central area 26.

In this example, external face 22B includes a metal pad 34 of external contacts allowing so-called contact communication to be established between chip 18 of module 16 and an external card reader (not shown), and the internal face 22A bears a metal pad 36 of internal contacts of integrated circuit 18 to electronic components incorporated into socket 12.

For example, integrated circuit 18 is encapsulated in a shell 19 of polymer resin and is thus adhesively bonded into the central area 26 of cavity 24. In addition, as illustrated in FIG. 1, this chip 18 of module 16 is connected by wire to the contacts of external pad 34 through vias 37 provided in socket 12. Thus, electrically conductive wires 40 connect integrated circuit 18 and external pad 34 by running through bores (or vias) 37 provided for this purpose. In addition, integrated circuit 18 is connected by conductive traces (not shown in the figure) to internal contacts pad 36.

In a variant that is not illustrated, chip 18 may be assembled according to another assembly procedure, such as for example a <<flip-chip>> type chip assembly process, which is to say that all the chip's contacts, in the form of metal balls or bumps, are located on a single face. The chip is assembled upside down during assembly so that the balls or bumps will be bonded to the appropriate conductors on socket 12.

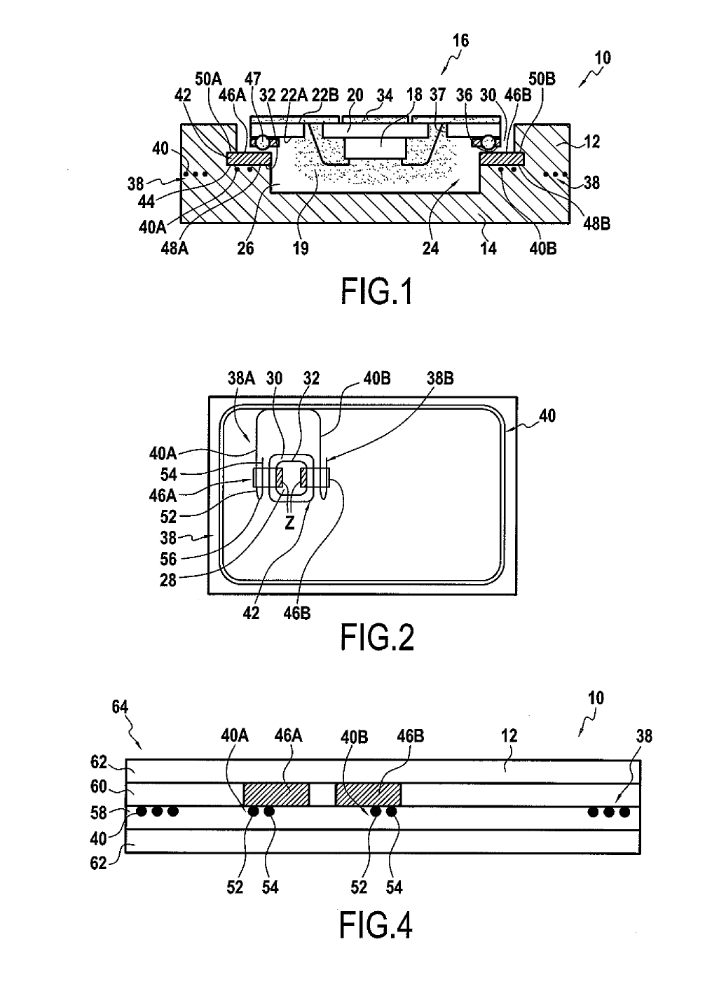

Referring to FIGS. 1 and 2, body 14 of integrated circuit card 10 incorporates a first component 38 provided with an electrical connection wire. Card 10 is preferably of the dual type and the first component 38 includes an antenna 38 provided with two electrical connection wires 40A, 40B constituting the end of wire 40 corresponding respectively to ends 38A, 38B of antenna 38.

Antenna 38 is for example made up of an electrically conductive wire 40 coiled in a plurality of turns, preferably along the periphery of socket 12, prolonged by the two free ends 40A, 40B of wire 40 of antenna 38. These end portions 40A, 40B constitute the electrical connection wires of antenna 38 allowing the said antenna 38 to be connected with other components held by socket 12.

Hereafter, components associated with the first end 38A of antenna 38 will be referred to with index A, and components associated with the second end 38B with index B.

In the example described, antenna 38 is connected to integrated circuit 18 held in socket 20 through a second component 42 provided with at least one electrical connection pad 44. This second component 42 is also incorporated into body 14 of card 10.

More particularly, the first 38 and second 42 components are electrically interconnected.

The second component 42 includes for example a metal contact land 46, and preferably two metal contact lands 46A, 46B, respectively for connecting each of the electrical connection wires 40A, 40B to first component 38.

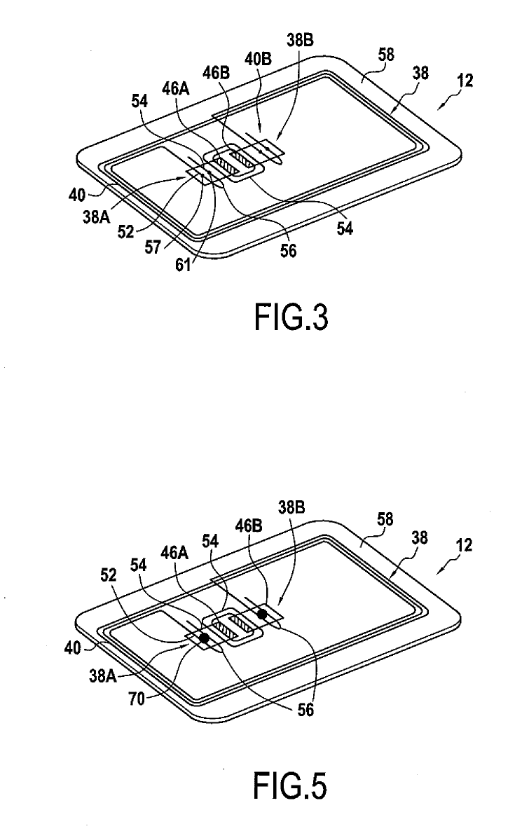

In the description that follows, the connection of antenna 38 to the first land 46A, shown in FIG. 3, will be described in detail. Of course, the detailed description of the connection of the first land 46A also applies to the connection of the second land 46B shown in the figures.

Land 46A is provided with a first pad 48A for electrical connection to wire 40A, and with a second pad 50A, opposite the first pad 48A, for electrically connecting land 46A to integrated circuit 18.

In the example illustrated, the first 48A and second 50A pads are respectively defined by the first and second opposed faces of land 46A.

More particularly, connection wire 40A of antenna 38 is routed along at least one out-and-back path so as to form at least first 52 and second 54 rectilinear portions on the outward and return paths respectively, running though at least one loop 56 interconnecting the two portions 52 and 54.

More particularly, electrical connection wire 40A is attached to metal pad 48A corresponding to second component 42, at at least one electrical conduction point, in such a way that each of the rectilinear portions 52, 54 are connected to pad 44A, 44B. For example, the electrical conduction point is brought about by bonding, thermocompression or any other suitable process.

In a first embodiment of the invention illustrated in FIG. 3, each of the rectilinear portions is connected to pad 44A, 44B at at least two electrical conduction points 57, 61 laid out so that each runs respectively over the two rectilinear portions 52, 54.

In a variant that is not illustrated, antenna 38 can be directly connected to integrated circuit 18 without requiring the intermediate connection with the contact pads. In this case, the integrated circuit is provided with a post including an electrical connection pad for the antenna's connection wire.

As shown in detail in FIG. 3, end 40A of wire 40 is positioned with respect to pad 48A in such a way that the two rectilinear portions 52, 54 of wire 40 run facing pad 48A.

In the example illustrated, the second rectilinear portion 54 includes end 40A of the antenna wire. This portion is preferably arranged so that end 40A extends beyond the surface of pad 48A. This allows better anchorage of end 38A of antenna 38 in socket 14.

Loop 56 preferably also extends beyond connection pad 48A and is embedded in the mass of material forming body 14. This makes it possible in particular to anchor antenna 38 in socket 12.

Attachment of wire 40A to corresponding pad 44A is preferably carried out by thermocompression, for example using ultrasonic means. As a variant, attachment can be accomplished by laser bonding, by adhesive bonding, etc.

In addition, socket 12 is preferably formed by lamination of a plurality of layers superimposed to form a stack into which are inserted the various electronic components of card 10 such as antenna 38 and contact lands 46. Thus, one of the layers of stack 64 incorporates at least one of the two components. Module 16 is inserted once the lamination of the layers is accomplished.

In the example described, integrated circuit 18 is not in direct contact with lands 46A, 46B, but is electrically connected to lands 46A, 46B through contacts in internal metal pad 36, this internal metal pad 36 being itself connected to electrical lands 46A, 46B by an electrically insulating adhesive into which are incorporated electrically conductive particles 47 (FIG. 1).

Referring to FIG. 4, socket 12 includes at least one internal layer 58 bearing antenna 38 and a second internal layer 60 bearing lands 46. These layers are made within an insulating material such as a plastic.

In addition, these first 58 and second 60 layers are interleaved between two external layers 62, called compensation layers, whose function is to compensate for possible surface defects in internal layers 58 and 62.

Preferably, as illustrated in the figures, both lands 46A, 46B run substantially within the same plane of socket 12, defined by internal layer 58.

Antenna 38 is incorporated into central layer 58 using a conventional technique (screen printing, engraving, wire insertion, ultrasound, etc.).

For the sake of simplicity, only the four central layers 58, 60 and 62 of stack 64, resulting from this superposition, are shown in FIG. 4. Of course, other layers not shown can be added to the stack.

A second embodiment of the invention has been shown in FIG. 5. In this figure, elements analogous to those of the preceding figure have been given identical reference numbers.

In this second embodiment, rectilinear portions 52, 54 are connected to pad 44A, 44B at a conduction point 70 arranged to as to extend over both rectilinear portions 52, 54.

Thanks to this particular arrangement, the connection between the land and antenna 38 is more rigid. In fact, due to the fact that point 70 extends over both portions 52, 54 of loop 56, the connection is reinforced because the equivalent diameter of the two portions 52, 54 is larger than the diameter of a portion 52 or 54 alone. Thus, mechanical performance in bending, torsion is improved and the resulting product is more reliable.

In the first and second embodiments illustrated by FIGS. 3 and 5, it is noted that the wire portions 52 or 54 are arranged on each land at a substantial distance from the location provided for cavity 24 suited to receive the integrated circuit module. It is thus possible to avoid damage to wire 40 of antenna 38 during the machining of cavity 24.

The principal steps of a process for manufacturing an integrated circuit card including two components interconnected by a process according to the invention will now be described.

During a first step, antenna 38 is incorporated into a substrate constituting the first internal layer 58, by ultrasonic means for example. Wire 40 of antenna 38 is thus coiled so as to form turns around the periphery of the socket. Electrical connecting wires 40A, 40B are also arranged along the predefined path, as described above.

Then, two holes having forms complementary to those of the lands are made in the substrate constituting the second internal layer 58. Contact lands 46A, 46B are then positioned in the corresponding holes.

Internal layers 58, 60 are then stacked in such a way that the rectilinear portions of wires 40A, 40B coincide substantially in coincidence with pads 48A, 48B of lands 46A, 46B.

The electrical connecting wires are then attached to the corresponding lands 46A, 46B by forming two conduction points on each portion of the electric connection wires in such a way as to establish the two electrical connections.

Preferably, and as shown in FIG. 3, for carrying out the operation of attaching the two components 38 and 42 to one another, layer 58 which incorporates the lands is placed below the layer incorporating antenna 38. The stack made up of these two layers is then turned over once the attachment is accomplished.

Internal layers 58 and 60 are then interleaved between the two external plastic layers 62 and possibly other external layers are added to form a stack which is then subjected to a lamination cycle.

Upon completion of the lamination cycle, a card body is obtained in which the two lands 46A, 46B and antenna 38 are embedded. The card body 14 preferably has a thickness substantially of the order of 760 microns, satisfying integrated circuit card standard ISO 7816.

Module 16 is then inserted in body 14 of card 10. Thus, a cavity 24 is then formed in body 14 of card socket 12 at the predefined location. This cavity 24 is formed in two operations, a first operation to carry out a wide spot-facing corresponding to peripheral area 30 and a second operation to carry out a small spot-facing corresponding to the deeper central area 26.

To this end, a suitable milling tool machines cavity 24, for example by rotation of a milling bit. Tool 56 first forms the large spot face, which exposes part of each land 46, then forms the small spot face so as to partially cut out each end of lands 46. The cut-out areas Z in the lands are shown by hatching in FIG. 2.

Exposing part of each land 46 also allows two pads to be formed for electrical connection with integrated circuit 18.

The socket 12 thus obtained at the completion of these various steps includes antenna 38 and lands 46 as laid out in FIG. 2.

Module 16 is then inserted into cavity 24 in such a way that the edges of internal face 22A of module socket 20 rest on the bearing surface 32 and in such a way that that internal contacts 36 of the internal pad of module 16 coincide with the exposed part of each land 46 (FIG. 1).

Thanks to the invention, the contact lands are reliably attached to antenna 38 by giving this attachment strength in torsion and in bending.

It is understood that the embodiments that have just been described are not limiting in character and that they may be given any desirable modification without thereby departing from the scope of the invention.

In particular, it would be in accordance with the invention to apply the connection process to two components of a printed or other circuit socket without applying it exclusively to an integrated circuit card socket.

What is claimed is:

1. A process for electrically connecting a first component provided with an electrical connection wire and a second component provided with an electrical connection pad, comprising the steps of:
routing of the wire along at least one out-and-back path so as to form at least a first and a second substantially rectilinear portions in the outward and return paths, running through at least one loop connecting the two portions; and
attaching the wire to the pad at at least one electrical conduction point so that each of the rectilinear portions is connected to the pad.

2. The process according to claim 1, in which each of the rectilinear portions is connected to the pad at at least two electrical conduction points arranged so that each extends respectively over the two rectilinear portions.

3. The process according to claim 1, in which the rectilinear portions are connected to the pad at a conduction point arranged to extend over the two rectilinear portions.

4. The process according to claim 1, in which the step of attaching the wire to the pad is carried out by thermocompression.

5. The process according to claim 1, in which the wire is positioned with respect to the connection pad in such a way that the two rectilinear portions of the wire run facing the pad.

6. The process according to claim 1, in which one of the rectilinear portions including the end of the wire, this portion is arranged so that the end extends beyond the pad.

7. An integrated circuit card socket, including a card body formed in a mass of material incorporating first and second components provided respectively with an electrical connection wire and an electrical connection pad, wherein the first and second components are connected according to a process having the following steps:
routing of the wire along at least one out-and-back path so as to form at least a first and a second substantially rectilinear portions in the outward and return paths, running through at least one loop connecting the two portions; and
attaching the wire to the pad at at least one electrical conduction point so that each of the rectilinear portions is connected to the pad.

8. The socket according to claim 7, in which the body is formed by lamination of a stack of layers, one of the layers incorporating at least one of the two components.

9. The socket according to claim 7, in which the second component is chosen to be either a contact land, or a connection post for an electronic component such as an integrated circuit.

10. The socket according to claim 7, in which the loop extending beyond the pad is embedded in the mass of the material constituting the body.

11. The socket according to claim 7, in which the second component includes another connection pad and the first component is provided with another connection wire, the pads and the wires being interconnected.

12. The socket according to claim 7, in which the second component includes at least one contact land, opposite the first electrical connection pad for an integrated circuit held by the socket.

13. The socket according to claim 7, in which the first component includes an antenna having a plurality of turns running around the periphery of the socket.

14. An integrated circuit card, including an integrated circuit and a card socket bearing the integrated circuit provided with a cavity for receiving the integrated circuit, wherein, the card socket comprises a card body formed in a mass of material incorporating first and second components provided respectively with an electrical connection wire and an electrical connection pad, the first component having an antenna and the second component having a connection post for an integrated circuit or a contact land for connecting the antenna to the integrated circuit.
